(19) United States
(12) Patent Application Publication
(10) Pub. No.: US 2026/0107738 A1
(43) Pub. Date: Apr. 16, 2026

(54) SEMICONDUCTOR MANUFACTURING APPARATUS INCLUDING STAGE CONFIGURED TO LEVITATE

(71) Applicant: Samsung Electronics Co., Ltd., Suwon-si (KR)

(72) Inventors: Jaeho Hong, Suwon-si (KR); TAEHONG MIN, Suwon-si (KR); Sangjun Park, Suwon-si (KR); TAE-HOI PARK, Suwon-si (KR); SANG-HO YUN, Suwon-si (KR)

(21) Appl. No.: 19/345,935

(22) Filed: Sep. 30, 2025

(30) Foreign Application Priority Data
Oct. 10, 2024 (KR) 10-2024-0137494

(51) Int. Cl. H01L 21/683; H01L 21/67

(52) U.S. Cl. CPC H10P 72/722; H10P 72/0428

(57) ABSTRACT

A semiconductor manufacturing apparatus includes a bonding chamber including a lower frame and an upper frame provided on the lower frame and having an internal space, a lower plate provided on the lower frame within the internal space, including first magnets arranged in a matrix, and having a first surface and a second surface opposing the first surface, a lower stage including at least one second magnet and configured to levitate above the first magnets using magnetic force, a current controller configured to apply current to the first magnets or the at least one second magnet and control at least one of a direction and an intensity of the current, an upper plate having a third surface facing the first surface, the upper plate connected to a lower surface of the upper frame, and an upper stage provided on the third surface of the upper plate.

### CROSS-REFERENCE TO RELATED APPLICATION(S)

This U.S. non-provisional application claims priority under 35 USC § 119 to Korean Patent Application No. 10-2024-0137494, filed on Oct. 10, 2024, in the Korean Intellectual Property Office, the disclosure of which is herein incorporated by reference in its entirety.

### BACKGROUND

Example embodiments relate to a semiconductor manufacturing apparatus.

Semiconductor devices may be manufactured through various manufacturing processes. For example, semiconductor devices may be manufactured by performing processes such as deposition, photolithography, etching, or ion implantation. Recent advances in semiconductor manufacturing processes have led to a proposal of a substrate bonding process of bonding two or more substrates to each other. In such bonding processes, two substrates may be directly bonded to each other without an additional medium between the two substrates, using a semiconductor manufacturing apparatus (for example, a substrate bonding apparatus).

### SUMMARY

Example embodiments provide a semiconductor manufacturing apparatus reducing vibrations of a substrate during a bonding process.

According to an example embodiment, a semiconductor manufacturing apparatus includes a bonding chamber including a lower frame and an upper frame provided on the lower frame and having an internal space, a lower plate provided on the lower frame within the internal space, including first magnets arranged in a matrix, and having a first surface and a second surface opposing the first surface, a lower stage including at least one second magnet and configured to levitate above the first magnets using magnetic force, a current controller configured to apply current to the first magnets or the at least one second magnet and control at least one of a direction and an intensity of the current, an upper plate having a third surface facing the first surface, the upper plate connected to a lower surface of the upper frame, and an upper stage provided on the third surface of the upper plate.

According to an example embodiment, a semiconductor manufacturing apparatus includes a bonding chamber including a lower frame and an upper frame provided on the lower frame and having an internal space, a lower plate provided on the lower frame, including permanent magnets arranged in a matrix, and having a first surface and a second surface opposing the first surface, a lower stage configured to levitate above first magnets using magnetic force and including at least one electromagnet and a current controller configured to apply current to the at least one electromagnet and control at least one of a direction and an intensity of the current, an upper plate having a third surface facing the first surface, the upper plate connected to a lower surface of the upper frame, and an upper stage provided on the third surface of the upper plate.

According to an example embodiment, a semiconductor manufacturing apparatus includes a bonding chamber including a lower frame and an upper frame provided on the lower frame and having an internal space, a lower plate provided on the lower frame, the lower plate including electromagnets arranged in a matrix, the lower plate having a first surface and a second surface opposing the first surface, a current controller configured to apply current to the electromagnets and to control at least one of a direction and an intensity of the current, a lower stage configured to levitate above the electromagnets using magnetic force and including at least one permanent magnet, an upper plate having a third surface facing the first surface, the upper plate connected to a lower surface of the upper frame, and an upper stage provided on the third surface of the upper plate.

### BRIEF DESCRIPTION OF DRAWINGS

FIG. 1 is a cross-sectional view of a semiconductor manufacturing apparatus according to an example embodiment.

FIG. 2 is a plan view of a lower chuck of a semiconductor manufacturing apparatus according to an example embodiment.

FIG. 3 is an enlarged view of portion ‘A’ of FIG. 2.

FIG. 4 is a cross-sectional view taken along line I-I′ of FIG. 3.

FIG. 5 is a plan view of a lower stage of a semiconductor manufacturing apparatus according to an example embodiment.

FIG. 6 is a cross-sectional view taken along the line I-I′ of FIG. 5.

FIG. 7 is a diagram illustrating simulation data of a semiconductor manufacturing apparatus according to a comparative example.

FIG. 8 is a diagram illustrating simulation data of a semiconductor manufacturing apparatus according to an example embodiment.

FIG. 9 is an enlarged view corresponding to portion ‘A’ of FIG. 2 and illustrating a semiconductor manufacturing apparatus according to an example embodiment.

FIG. 10 is a cross-sectional view taken along line I-I′ of FIG. 9.

FIG. 11 is a plan view of a lower stage of a semiconductor manufacturing apparatus according to an example embodiment.

FIG. 12 is a cross-sectional view taken along line I-I′ of FIG. 11.

FIG. 13 is a plan view of a lower plate and a lower stage of a semiconductor manufacturing apparatus according to an example embodiment.

FIG. 14 is an enlarged view of portion ‘A’ of FIG. 13.

FIG. 15 is an enlarged view corresponding to portion ‘A’ of FIG. 13 and illustrating a semiconductor manufacturing apparatus according to an example embodiment.

FIG. 16 is a plan view of a lower plate and a lower stage of a semiconductor manufacturing apparatus according to an example embodiment.

FIG. 17 is a cross-sectional view corresponding to line I-I′ of FIG. 5 and illustrating a semiconductor manufacturing apparatus according to an example embodiment.

FIG. 18 is a cross-sectional view illustrating a charging method of a lower stage of a semiconductor manufacturing apparatus according to an example embodiment.

FIG. 19 is a plan view of a lower stage of a semiconductor manufacturing apparatus according to an example embodiment.

FIG. 20 is a cross-sectional view taken along line I-I′ of FIG. 19.

FIG. 21 is a plan view of a lower stage of a semiconductor manufacturing apparatus according to an example embodiment.

FIG. 22 is a cross-sectional view taken along line I-I′ of FIG. 21.

FIG. 23 is a plan view of a lower stage of a semiconductor manufacturing apparatus according to an example embodiment.

FIG. 24 is a cross-sectional view taken along line I-I′ of FIG. 23.

### DETAILED DESCRIPTION

Hereinafter, example embodiments will be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

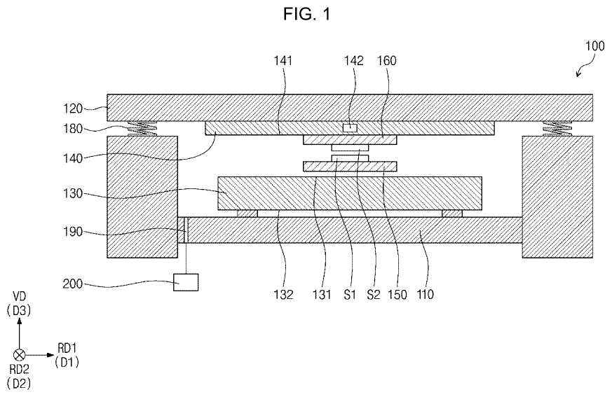

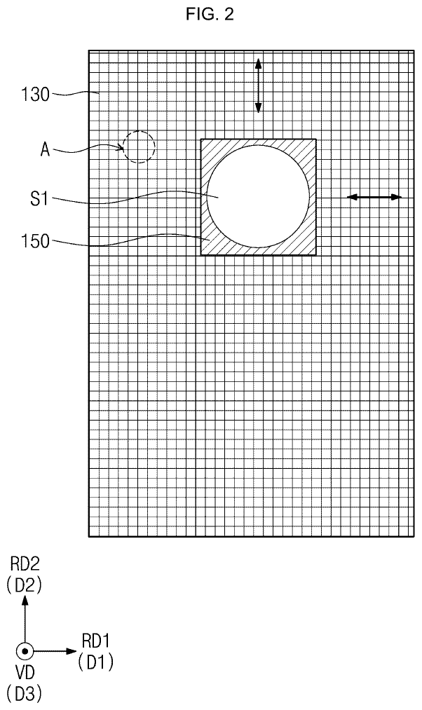

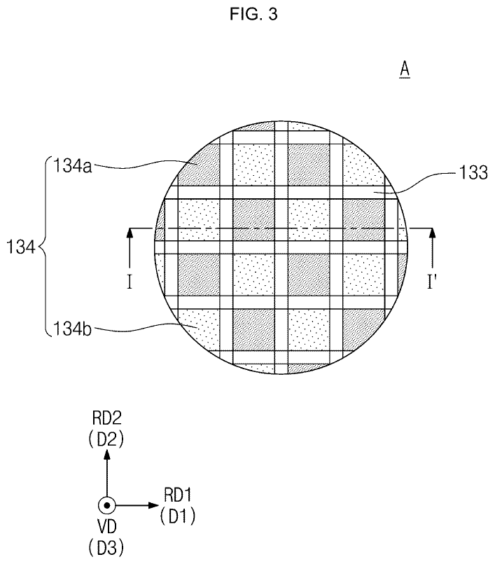

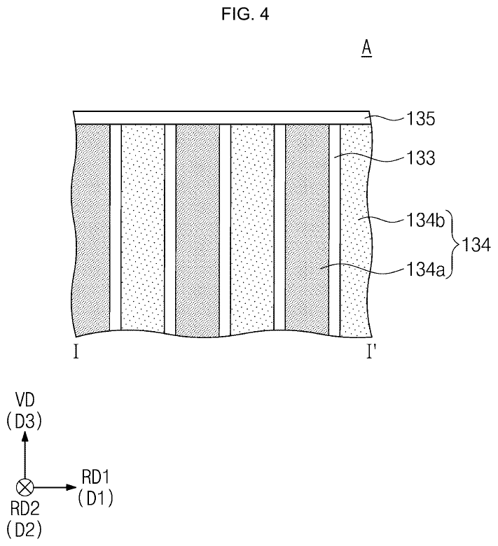

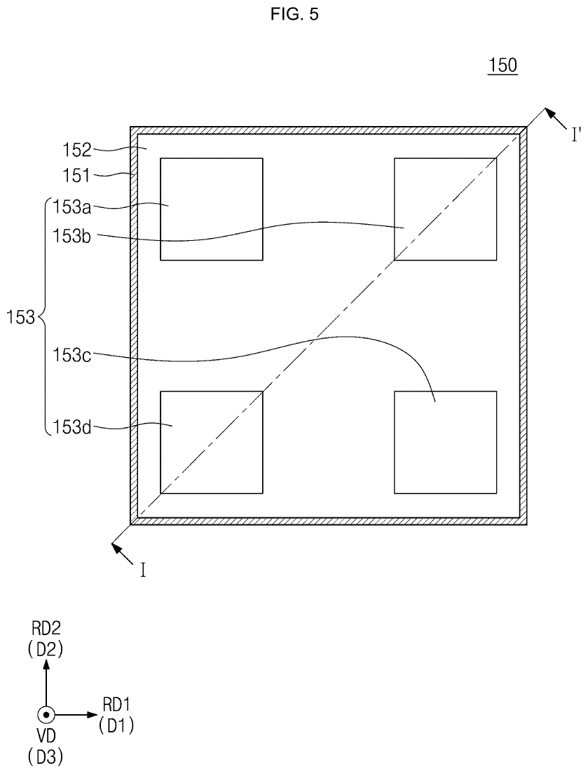

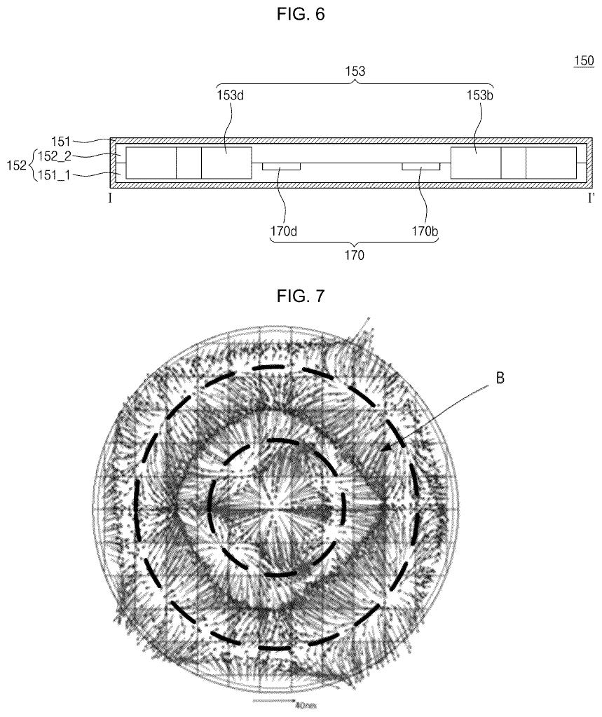

FIG. 1 is a cross-sectional view of a semiconductor manufacturing apparatus according to an example embodiment. FIG. 2 is a plan view of a lower chuck of a semiconductor manufacturing apparatus according to an example embodiment. FIG. 3 is an enlarged view of portion ‘A’ of FIG. 2. FIG. 4 is a cross-sectional view taken along line I-I′ of FIG. 3. FIG. 5 is a plan view of a lower stage of a semiconductor manufacturing apparatus according to an example embodiment. FIG. 6 is a cross-sectional view taken along the line I-I′ of FIG. 5. In an example embodiment, the semiconductor manufacturing apparatus may be a bonding apparatus for bonding two substrates to each other.

Referring to FIGS. 1 and 3 to 6, the semiconductor manufacturing apparatus according to an example embodiment may include a bonding chamber 100. The bonding chamber 100 may include a lower frame 110, an upper frame 120, a lower plate 130, an upper plate 140, a lower stage 150, an upper stage 160, a current control portion 170, a connecting portion 180, and an exhaust port 190. In an example embodiment, the semiconductor manufacturing apparatus may further include a vacuum pump 200 connected to the exhaust port 190. The lower plate 130 and the lower stage 150 may constitute a lower chuck, and the upper plate 140 and the upper stage 160 may constitute an upper chuck.

The bonding chamber 100 may provide an internal space for performing a bonding process. The lower frame 110, the upper frame 120, and the connecting portion 180 may be coupled to each other to define the internal space. The lower frame 110 may include a bottom portion and a wall portion extending upward from an edge of the bottom portion. The bottom portion and the wall portion of the lower frame 110 may correspond to or may be a bottom portion and a wall portion of the bonding chamber 100, respectively. In addition, the upper frame 120 may correspond to or may be a ceiling portion of the bonding chamber 100. For example, the wall portion, the bottom portion of the lower frame 110 and the ceiling portion of the bonding chamber 100 may define the internal space. In an example embodiment, the upper frame 120 may be configured to be removable from an upper end of the wall portion of the lower frame 110. For example, the upper frame 120 may be coupled to the upper end of the wall portion of the lower frame 110 to close the internal space of the bonding chamber 100 and may be separated from the lower frame 110 to open the internal space. When the internal space is opened (e.g., by separating the upper frame 120 from the lower frame 110), the lower stage 150 and/or substrates S1 and S2 may enter or exit the bonding chamber 100. However, the inventive concept is not limited thereto. In an example embodiment, the lower frame 110 may be provided with an entrance, not illustrated, penetrating through the wall portion of the lower frame 110. The lower stage 150 and/or the substrates S1 and S2 may enter into the internal space of the bonding chamber 100 through the entrance, or exit the bonding chamber 100 through the entrance. The semiconductor manufacturing apparatus may include a cover that may open and close the entrance.

The lower plate 130 may be provided on the lower frame 110 within the internal space. The lower plate 130 may have a first surface 131 and a second surface 132 opposing the first surface 131. In addition, the lower plate 130 may include a lower plate case 133, first magnets 134, and an insulating plate 135. As illustrated in FIG. 2, the lower plate 130 may have a rectangular shape in a plan view. A direction parallel to a first side of the lower plate 130 may be defined as a first reference direction RD1, and a direction parallel to a second side of the lower plate 130 may be defined as a second reference direction RD2. The first and second reference directions RD1 and RD2 may be parallel to the first surface 131 of the lower plate 130 and may intersect (e.g., be perpendicular to) each other. In an example embodiment, the first and second reference directions RD1 and RD2 may be perpendicular to each other. In addition, a vertical direction VD illustrated in FIG. 2 may be perpendicular to the first surface 131 of the lower plate 130.

The lower plate case 133 may define pattern spaces in which the first magnets 134 are provided, respectively. For example, each of the pattern spaces may be a space in which a first magnet 134 is disposed. The pattern spaces formed by or surrounded by the lower plate case 133 may be spaced apart from each other. For example, the lower plate case 133 may be provided between the first magnets 134 to space the first magnets 134 apart from each other. Each of the pattern spaces formed by the lower plate case 133 may have a rectangular shape in a plan view, e.g., may be a square in the plan view. For example, each of the pattern spaces may have a hexahedral shape (e.g., a cube shape) such that each pattern space is a hexahedral space (e.g., a cubic space). For example, the lower plate case 133 may be formed of crisscrossing partition walls dividing an upper portion of the lower plate into a plurality of rectangular spaces which are the pattern spaces. For example, the lower plate case 133 may be a grid-like structure. In an example embodiment, each of the pattern spaces may have sides parallel to the first reference direction RD1 and sides parallel to the second reference direction RD2, as illustrated in FIG. 3. For example, each of the first magnets 134 may have a cuboid shape, e.g., may be a cuboid. In certain embodiments, each of the first magnets 134 may have a cylindrical shape. In certain embodiments, when the first magnets 134 have cylindrical shapes, the pattern spaces may also have cylindrical shapes corresponding to the shapes of the first magnets 134. In an example embodiment, the first magnets 134 may be arranged in a matrix, e.g., in the first and second reference directions RD1 and RD2, as illustrated in FIG. 3. A polarity of each of the first magnets 134 may be different from polarities of adjacent first magnets 134 in the first and second reference directions RD1 and RD2. For example, polarities of upper ends of the first magnets 134 closest to each other in the first direction and the second direction may be different from each other. For example, in an example embodiment, the first magnets 134 may be permanent magnets and may include N-pole magnets 134a and S-pole magnets 134b. The N-pole magnets 134a and the S-pole magnets 134b may be alternately arranged in the first reference direction RD1 and may be alternately arranged in the second reference direction RD2. For example, the N-pole magnets 134a may be magnets having N-pole upper ends exposed on an upper surface of the lower plate 130, and the S-pole magnets 134b may be magnets having S-pole upper ends exposed on the upper surface of the lower plate 130. For example, the N-pole magnets 134a may have S-poles at opposite ends (e.g., at lower ends), and the S-pole magnets 134b may have N-poles at opposite ends (e.g., at lower ends). The insulating plate 135 may cover the first magnets 134. For example, the insulating plate 135 may cover/contact top surfaces of the first magnets 134. In an example embodiment, magnetic strengths of the N-pole magnets 134a may be different from magnetic strengths of the S-pole magnets 134b. For example, the magnetic strengths of the N-pole magnets 134a may be smaller or greater than the magnetic strengths of the S-pole magnets 134b.

The upper plate 140 may be provided on a lower surface of the upper frame 120 within the internal space. For example, the upper plate 140 may be attached/connected to the upper frame 120 (e.g., to the lower surface of the upper frame 120). The upper plate 140 may have a third surface 141 facing the first surface 131 of the lower plate 130. In certain embodiments, the upper plate 140 may include a pressurizing portion 142. The pressurizing portion 142 may be provided in the upper plate 140 such that pressure is applied to the upper stage 160 to press the second substrate S2.

The lower stage 150 may be provided on the lower plate 130 within the internal space. For example, the lower stage 150 may be configured to accommodate the first substrate S1. For example, the first substrate S1 may be loaded on the upper surface of the lower stage 150 during a bonding process. In an example embodiment, the lower stage 150 may fix the first substrate S1 using electrostatic force.

In an example embodiment, the lower stage 150 may be configured to levitate above the first magnets 134 of the lower plate 130 using magnetic force. In addition, the lower stage 150 may include a lower stage case 151, an insulating layer 152, a second magnet 153, and a current control portion 170.

The second magnet 153 may be provided within the lower stage case 151. The second magnet 153 may be an electromagnet. A polarity and magnetic strength of the second magnet 153 may be controlled by electric current applied to the second magnet 153. For example, the second magnet 153 may include a hollow coil. However, the inventive concept is not limited thereto. In an example embodiment, a plurality of second magnets 153 may be provided in the lower stage 150. In an example embodiment, at least two second magnets 153 may be provided within the lower stage case 151. For example, four second magnets 153a, 153b, 153c, and 153d may be provided within the lower stage case 151. The four second magnets 153a, 153b, 153c, and 153d may be spaced apart from each other. In addition, the four second magnets 153a, 153b, 153c, and 153d may be arranged to surround a central region of the lower stage 150 in a plan view. In addition, the four second magnets 153a, 153b, 153c, and 153d may be spaced apart from a center of the lower stage 150 at equal distances (equidistantly) and may be arranged at equal angles (equiangularly) in a clockwise direction, in a plan view.

The current control portion 170 may be electrically connected to the second magnet 153, which is an electromagnet. The current control portion 170 may be configured to apply a current (electric current) to the second magnet 153 and may be configured to control at least one of the direction and magnitude of the current. When four second magnets 153a, 153b, 153c, and 153d are provided in the lower stage 150, four current control portions 170 may be included in the lower stage 150, and the four current control portions may be respectively connected to the four second magnets 153a, 153b, 153c, and 153d. In FIG. 6, two current control portions 170b and 170d, respectively connected to two second magnets 153b and 153d, are shown in the drawings along the cross-section line I-I′ of FIG. 5. As a result, the magnetic forces of the four second magnets 153a, 153b, 153c, and 153d may be controlled independently of each other. In addition, the current control portion 170 may control at least one of the direction and magnitude of the current based on an input signal, and may control at least one of the direction and magnitude of the current based on a set algorithm or internal program. The insulating layer 152 may be provided within the lower stage case 151. In addition, the insulating layer 152 may have a single-layer structure or a multilayer structure. In an example embodiment, the insulating layer 152 may include a lower portion 152_1 that is in contact with a bottom portion of the lower stage case 151 and an upper portion 152_2 provided on the lower portion 152_1. The lower portion 152_1 of the insulating layer 152 may cover the second magnets 153b and 153d and the current control portions 170b and 170d. The upper portion 152_2 of the insulating layer may cover the second magnets 153a, 153b, 153c, and 153d. Although not illustrated in the drawings, the lower portion 152_1 of the insulating layer may cover the four second magnets 153a, 153b, 153c, and 153d and may cover the current control portions, respectively corresponding to the four second magnets 153a, 153b, 153c, and 153d. For example, the lower portion 152_1 of the insulating layer 152 may cover/contact bottom surfaces and/or lower portions of side surfaces of the second magnets 153a, 153b, 153c, and 153d and the corresponding current control portions 170, and the upper portion 152_2 of the insulating layer may cover/contact top surfaces and upper portions of side surfaces of the second magnets 153a, 153b, 153c, and 153d and top surfaces of the corresponding current control portions 170. For example, the second magnet 153 and/or the current control portion 170 may be provided within the insulating layer 152, e.g., such that the second magnets 153 and the current control portions 170 are enclosed in the insulating layer 152. Current control portions 170 described in the present disclosure may be current controllers configured to supply current to electromagnets installed in the semiconductor manufacturing apparatus.

Each of the current control portions (or current controllers) 170 may include one or more of the following components: at least one central processing unit (CPU) configured to execute computer program instructions to control electric current, random access memory (RAM) and read only memory (ROM) configured to access and store command and information and computer program instructions, input/output (I/O) devices configured to provide input and/or output to a processing controller (e.g., keyboard, mouse, display, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), flash drives, any type of tangible and non-transitory storage medium) where data and/or instructions can be stored. In addition, the current control portions or the current controllers 170 may include network interfaces that provide wireless and/or wire line digital and/or analog interface to one or more networks over one or more network connections, and a bus that allows communication among the various disclosed components of the controller.

The upper stage 160 may be provided on the third surface 141 of the upper plate 140 within the internal space. In an example embodiment, the upper stage 160 may be configured to fix the second substrate S2. For example, the upper stage 160 may vacuum-adsorb the second substrate S2 onto the lower surface of the upper stage 160 using vacuum pressure. Alternatively, the upper stage 160 may fix the second substrate S2 onto the lower surface of the upper stage 160 using electrostatic force.

The connecting portion 180 may be provided between the lower frame 110 and the upper frame 120. For example, the connecting portion 180 may be provided between the upper end of the wall portion of the lower frame 110 and the edge of the upper frame 120. Accordingly, the connecting portion 180 may separate the internal space of the bonding chamber 100 from the outside. In an example embodiment, the connecting portion 180 may be a bellows. The bellows is contractible and/or expandable and thus may be configured to adjust a level of the upper frame 120.

The exhaust port 190 may be provided in the bottom portion or a wall portion of the lower frame 110, and the vacuum pump 200 may be connected to the exhaust port 190. The vacuum pump 200 may be configured to evacuate the internal space of the bonding chamber 100 to a vacuum state. For example, the vacuum pump 200 may draw air or gas from the bonding chamber 100 through the exhaust port 190.

Referring to FIGS. 2, 5, and 6, the lower stage 150 may be moved horizontally and/or vertically while levitating from the lower plate 130. In an example embodiment, the current control portion 170 may control at least one of the direction and magnitude of the current applied to the second magnet 153 such that the lower stage 150 is moved parallel to at least one of the first direction D1, the second direction D2, or the third direction D3. The first direction D1 may be a first horizontal moving direction of the lower stage 150, the second direction D2 may be a second horizontal moving direction of the lower stage 150, and the third direction D2 may be a vertical moving direction of the lower stage 150. The first and second directions D1 and D2 may be parallel to the first surface 131 of the lower plate 130 and may intersect (e.g., be perpendicular to) each other. The third direction D3 may be perpendicular to the first surface 131 of the lower plate 130. In an example embodiment, as illustrated in FIG. 2, when the first magnets 134 are arranged in a matrix in the first and second reference directions RD1 and RD2, the first and second directions D1 and D2 may be parallel to the first and second reference directions RD1 and RD2, respectively. The third direction D3 may be parallel to the vertical direction VD.

For example, the current control portions 170 may control the directions of the currents, respectively applied to the four second magnets 153a, 153b, 153c, and 153d, such that the lower stage 150 is moved parallel to at least one of the first direction D1 and the second direction D2. For example, two of the current control portions 170 may apply first currents in a first current direction to two second magnets 153b and 153c among the four second magnets 153a to 153d, while the remaining two current control portions 170 may apply second currents in a second current direction to the remaining two second magnets 153a and 153d. As a result, the two second magnets 153b and 153c may have the same polarity (e.g., the same polarity arrangement as each other) simultaneously, and the remaining two second magnets 153a and 153d may have the same polarity (e.g., the same polarity arrangement as each other) simultaneously. When two magnets have the same polarity arrangement as each other, directions of the same poles from respective center of the magnets may be the same. For example, when an N-pole of one of the two magnets having the same polarity arrangement is positioned at a top of the magnet and an S-pole of the one magnet is positioned at a bottom of the magnet, an N-pole of the other of the two magnets may be positioned at a top and an S-pole of the other magnet may be at a bottom of the other magnet. The lower stage 150 may move in the first direction D1 or in a direction opposite to the first direction D1. For example, when the lower stage 150 is moved, the polarity of bottom ends of the two second magnets 153b and 153c may be changed to be opposite to the polarity of top ends of the first magnets 134 provided at a front (e.g., at an immediate front) of the two second magnets 153b and 153c in a moving direction (for example, the first direction D1), and the polarity of bottom ends of the remaining two second magnets 153a and 153d may be changed to be the same as the polarity of top ends of the first magnets 134 that vertically overlap or align with each other. For example, to move the lower stage 150 in the first direction D1, the two second magnets 153b and 153c positioned in front may be attracted by the first magnets 134 positioned in front, and the other two second magnets 153a and 153d positioned at the back may be repulsed by the first magnets 134 vertically overlapping or aligning with the other two second magnets 153a and 153d. By repeatedly and timely switching the polarities of the second magnets 153a, 153b, 153c, and 153d, the lower stage 150 may move and/or change positions. As a result, the lower stage 150 may be moved horizontally using attractive force and repulsive force between the magnets.

For example, two of the current control portions 170 may apply third currents in a third current direction to two second magnets 153a and 153b among the four second magnets 153a to 153d, while the remaining two current control portions 170 apply fourth currents in a fourth current direction to the remaining two second magnets 153c and 153d. Accordingly, the two second magnets 153a and 153b may have the same polarity (e.g., the same polarity arrangement) simultaneously, and the remaining two second magnets 153c and 153d may have the same polarity (e.g., the same polarity arrangement) simultaneously. The lower stage 150 may be moved in the second direction D2, or in a direction opposite to the second direction D2. For example, when the lower stage 150 is moved, the polarity of bottom ends of the two second magnets 153a and 153b may be changed to be opposite to the polarity of top ends of the first magnets 134 provided at a front (e.g., at an immediate front) of the two second magnets 153a and 153b in a moving direction (for example, the second direction D2), and the polarity of bottom ends of the remaining two second magnets 153c and 153d may be changed to be the same as the polarity of top ends of the first magnets 134 that vertically overlap or align with each other. As a result, the lower stage 150 may be moved horizontally using attractive force and repulsive force between the magnets.

In an example embodiment, the current control portions 170 may control the directions of the currents applied to the four second magnets 153a, 153b, 153c, and 153d, thereby rotating the lower stage 150. For example, the current control portions 170 may control the directions of the currents applied to at least two of the four second magnets 153a to 153d such that the at least two electromagnets have the same polarity (e.g., the same polarity arrangement) simultaneously, thereby rotating the lower stage 150. For example, the polarity of a bottom end of each of the second magnets 153a. 153b, 153c, and 153d may be changed to be opposite to the polarity of a top end of the first magnets 134 provided at a front (e.g., at an immediate front) of the corresponding second magnet 153a, 153b, 153c, or 153d in a rotation direction, and/or the polarity of a bottom end of each of the second magnets 153a. 153b, 153c, and 153d may be changed to be the same as the polarity of a top end of the first magnet 134 when the second magnets153a. 153b, 153c, and 153d are vertically aligned with the first magnets 134 respectively. As a result, the lower stage 150 may rotate in the rotation direction using the attractive force between the magnets.

In an example embodiment, the current control portions 170 may control the magnitudes of the currents, respectively applied to the four second magnets 153a, 153b, 153c, and 153d, to move the lower stage 150 in the third direction D3 or in a direction opposite to the third direction D3.

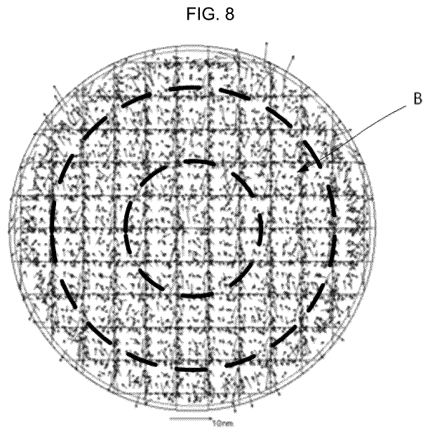

FIG. 7 is a diagram illustrating simulation data of a semiconductor manufacturing apparatus according to a comparative example, and FIG. 8 is a diagram illustrating simulation data of a semiconductor manufacturing apparatus according to an example embodiment.

Referring to FIGS. 1, 7, and 8, the semiconductor manufacturing apparatus according to an example embodiment may reduce misalignment, caused by an alignment process and a bonding process, by levitating or floating the lower stage 150 on the lower plate 130. When the alignment process and the bonding process are performed without separating the lower stage 150 from the lower plate 130, the likelihood of misalignment arising from vibration and friction of the apparatus may increase. FIG. 7 illustrates simulation data of a comparative example in which a bonding process is performed with a lower stage in contact with an upper surface of a lower plate. As illustrated in FIG. 7, portion ‘B’ is vulnerable to vibration and friction during an alignment process and a bonding process, resulting in more significant misalignment than other portions. For example, lengths of arrows in FIG. 7 may represent degrees of misalignment. FIG. 8 illustrates simulation data of a bonding process using a semiconductor manufacturing apparatus according to an example embodiment. As illustrated in FIG. 8, portion ‘B’ is well-aligned, which indicates that the semiconductor manufacturing apparatus according to an example embodiment significantly reduces effects of vibration and friction during the alignment process and the bonding process. As a result, the semiconductor manufacturing apparatus according to an example embodiment may significantly reduce misalignment to improve reliability of the bonded substrates S1 and S2.

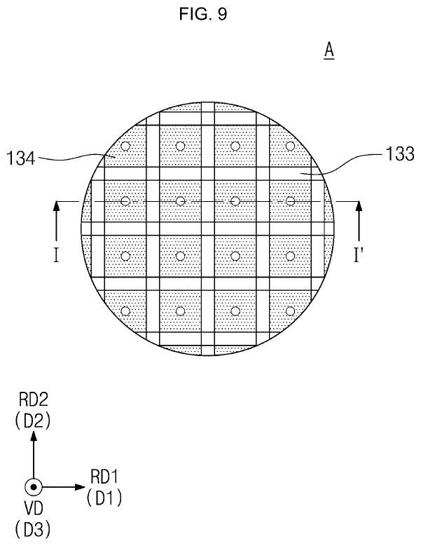

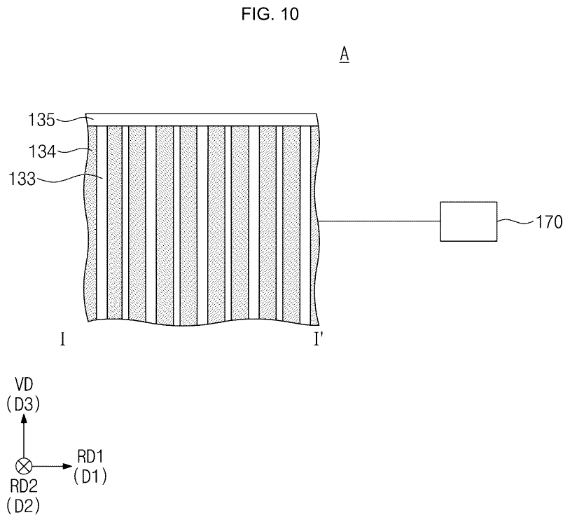

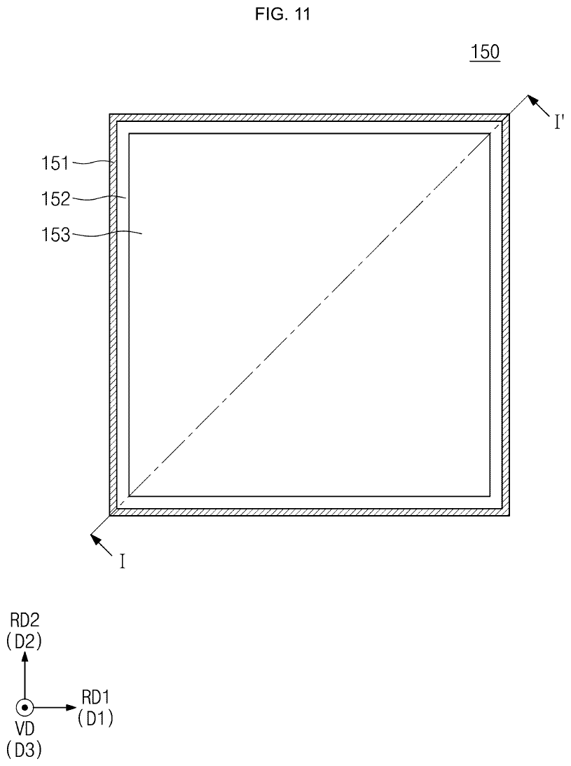

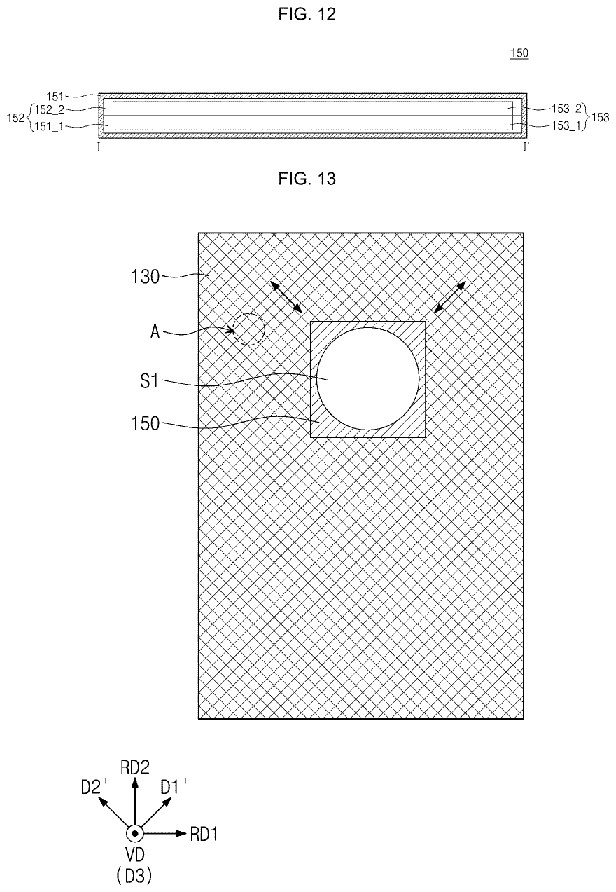

FIG. 9 is an enlarged view corresponding to portion ‘A’ of FIG. 2 and illustrating a semiconductor manufacturing apparatus according to an example embodiment, and FIG. 10 is a cross-sectional view taken along line I-I′ of FIG. 9. FIG. 11 is a plan view of a lower stage of a semiconductor manufacturing apparatus according to an example embodiment, and FIG. 12 is a cross-sectional view taken along line I-I′ of FIG. 11.

Referring to FIGS. 9 and 10, the first magnets 134 may be electromagnets, electrically connected to a current control portion 170 applying a current to the electromagnets. Accordingly, the lower plate 130 may further include the current control portion 170. The current control portion 170 may apply the current to the first magnets 134 and may control at least one of the direction and magnitude of the current. In addition, the current control portion 170 may be connected to each of the first magnets 134, and magnetic forces of the first magnets 134 may be controlled independently of each other.

Referring to FIGS. 11 and 12, the second magnet 153 may be a permanent magnet and include a lower portion 153_1 and an upper portion 153_2. The lower portion 153_1 may be an N pole, while the upper portion 153_2 may be an S pole and may be provided on the lower portion 153_1. For example, the lower portion 153_1 and the upper portion 153_2 of the second magnet 153 may have opposite polarities, e.g., the opposite polarities may be arranged in a vertical direction VD. However, a polarity direction/arrangement of the second magnet 153 is not limited to the above description, and the lower portion 153_1 of the second magnet 153 may be an S pole and the upper portion 153_2 of the second magnet 153 may be an N pole in certain embodiments. The lower portion 152_1 of the insulating layer may cover the lower portion 153_1 of the second magnet 153, and the upper portion 152_2 of the insulating layer may cover the upper portion 153_1 of the second magnet 153. The lower portion 152_1 of the insulating layer may cover/contact a bottom surface and lower portions of side surfaces of the second magnet 153, and the upper portion 152_2 of the insulating layer may cover/contact a top surface and upper portions of side surfaces of the second magnet 153. For example, the second magnet 153 may be provided within the insulating layer 152. For example, the lower portion 152_1 and the upper portion 152_2 of the insulating layer 152 may be formed by different/separate processes from each other.

Referring to FIGS. 2, 9, and 12, the lower stage 150 may be moved horizontally and/or vertically while levitating from the lower plate 130. In an example embodiment, the current control portion 170 may control at least one of the directions and magnitudes of currents applied to the first magnets 134 such that the lower stage 150 is moved parallel to at least one of the first direction D1, the second direction D2, or the third direction D3. In an example embodiment, as illustrated in FIG. 2, when the first magnets 134 are arranged in a matrix in the first and second reference directions RD1 and RD2, the first and second directions D1 and D2 may be parallel to the first and second reference directions RD1 and RD2, respectively. The third direction D3 may be parallel to the vertical direction VD. For example, the current control portions 170 may control the directions of the currents applied to each of the first magnets 134 such that the lower stage 150 is moved parallel to at least one of the first direction D1 and the second direction D2.

For example, the current control portions 170 may apply first currents in a first current direction to the first magnets 134 that vertically overlap the second magnet 153, and may apply second currents in a second current direction to a portion of the remaining first magnets 134 that do not vertically overlap the second magnet 153. As a result, the overlapping first magnets 134 may have the same polarity (e.g., the same polarity arrangement as each other) simultaneously, and the portion of the remaining first magnets 134 may have the same polarity (e.g., the same polarity arrangement as each other) simultaneously. The lower stage 150 may be moved in the first direction D1 or in a direction opposite to the first direction D1. For example, when the lower stage 150 is moved, the polarity of top ends of the portion of the remaining first magnets 134 disposed in the moving direction (for example, the first direction D1) may be changed to be opposite to the polarity of bottom ends of the second magnet 153, and the overlapping first magnets 134 may be changed to have at top ends the same polarity as a bottom end of the second magnet 153. As a result, the lower stage 150 may be moved horizontally using attractive force and repulsive force between the magnets.

For example, the current control portions 170 may apply third currents in a third current direction to the first magnets 134 that vertically overlap or align with the second magnet 153, and may apply fourth currents in a fourth current direction to a portion of the remaining first magnets 134 that do not vertically overlap or align with the second magnet 153. Accordingly, the overlapping first magnets 134 may have the same polarity (e.g., the same polarity arrangement as each other) simultaneously, and the portion of the remaining first magnets 134 may have the same polarity (e.g., the same polarity arrangement as each other) simultaneously. The lower stage 150 may be moved in the second direction D2 or in a direction opposite to the second direction D2. For example, when the lower stage 150 is moved, the polarity of top ends of the portion of the remaining first magnets 134 disposed in the moving direction (for example, the second direction D2) may be changed to be opposite to the polarity of bottom ends of the second magnet 153, and the overlapping first magnets 134 may be changed to have at top ends the same polarity as a bottom end of the second magnet 153. As a result, the lower stage 150 may be moved horizontally using attractive force and repulsive force between the magnets.

In an example embodiment, the current control portions 170 may control the directions of the currents applied to the first magnets 134, thereby rotating the lower stage 150. For example, the current control portions 170 may control the directions of the currents applied to at least a portion of the first magnets 134, which vertically overlap the second magnet 153, such that at least the portion of the first magnets 134 have the same polarity (e.g., the same polarity arrangement) simultaneously, thereby rotating the lower stage 150. For example, the polarity of top ends of at least the portion of the overlapping first magnets 134 may be changed to be opposite to the polarity of bottom ends of the second magnet 153. As a result, the lower stage 150 may be rotated in a rotation direction using the attractive force between the magnets.

In an example embodiment, the current control portions 170 may control the magnitudes of the currents, respectively applied to the first magnets 134, to move the lower stage 150 in the third direction D3 or in a direction opposite to the third direction D3.

In an example embodiment, the current control portions 170 may control the directions and magnitudes of the currents, respectively applied to the first magnets 134, to fix of stay the lower stage 150, e.g., at a position. For example, the current control portions 170 may apply first currents in a first current direction to the first magnets 134 that vertically overlap the second magnet 153, and may apply second currents in a second current direction to the remaining first magnets 134 that do not vertically overlap the second magnet 153. Accordingly, the overlapping first magnets 134 may have the same polarity (e.g., the same polarity arrangement as each other) simultaneously, and the remaining first magnets 134 may have the same polarity (e.g., the same polarity arrangement as each other) simultaneously. Accordingly, the lower stage 150 may be fixed, or may stay at a designated position. For example, the polarity of top ends of the overlapping first magnets 134 may be changed to be the same as the polarity of bottom ends of the second magnet 153, and the polarity of top ends of the remaining first magnets 134 may be changed to be opposite to the polarity of bottom ends of the second magnet 153. As a result, the lower stage 150 may be fixed or standstill at the same or similar location and/or level using the attractive force and the repulsive force between the magnets.

Referring to FIGS. 1, 5, 6, 10, and 11, the first magnets 134 may be electromagnets, and the second magnet 153 may be an electromagnet. Accordingly, current control portions 170 may be provided in the lower plate 130 and the lower stage 150, respectively. In addition, the current control portion 170 of the lower plate 130 may control the directions and magnitudes of the currents applied to the first magnets 134, and the current control portion 170 of the lower stage 150 may control the direction and magnitude of the current applied to the second magnet 153. In certain embodiments, each current control portion disposed in the lower stage 150 may apply currents to two or more electromagnets disposed in the lower stage.

Referring to FIGS. 2, 5, 6, 10, and 11, the semiconductor manufacturing apparatus according to an example embodiment may be configured to move the lower stage 150 on the lower plate 130. In an example embodiment, the current control portions 170 may control at least one of the directions and magnitudes of the currents applied to the first magnets 134 and at least one of the direction and magnitude of the current applied to the second magnet 153 to move the lower stage 150 to at least one of the first direction D1, the second direction D2, or the third direction D3.

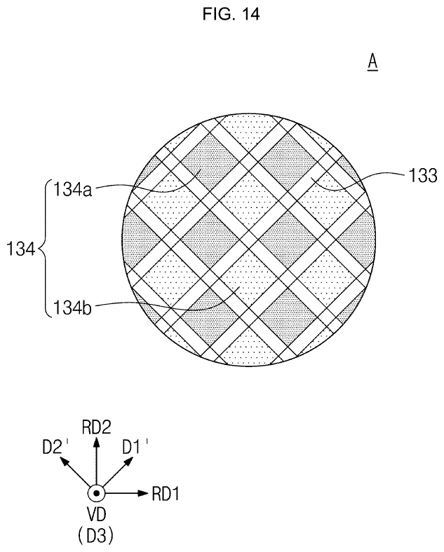

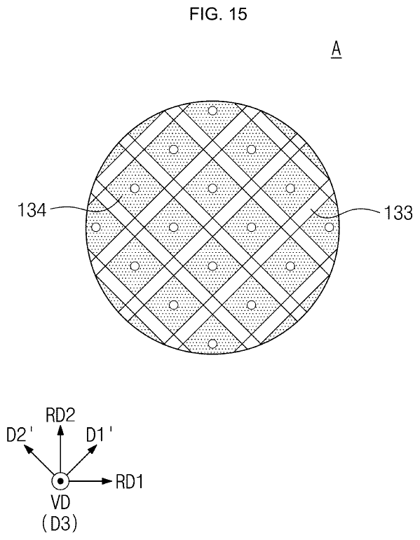

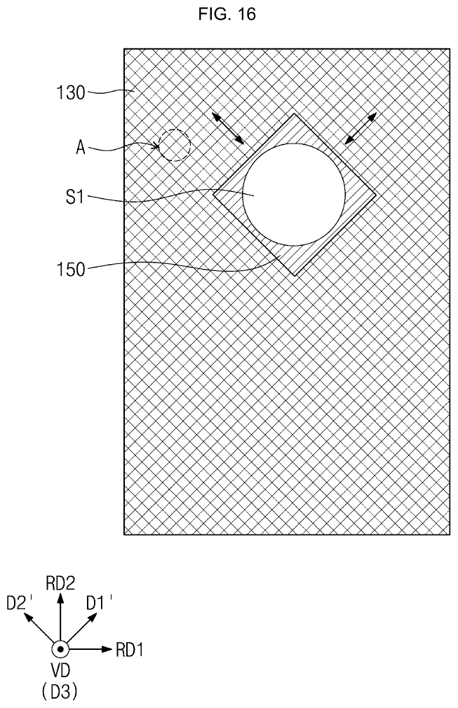

FIG. 13 is a plan view of a lower plate and a lower stage of a semiconductor manufacturing apparatus according to an example embodiment, and FIG. 14 is an enlarged view of portion ‘A’ of FIG. 13. FIG. 15 is an enlarged view corresponding to portion ‘A’ of FIG. 13 and illustrating a semiconductor manufacturing apparatus according to an example embodiment. FIG. 16 is a plan view of a lower plate and a lower stage of a semiconductor manufacturing apparatus according to an example embodiment. A first direction D1′ may be a third horizontal moving direction of the lower stage 150, and a second direction D2′ may be a fourth horizontal moving direction of the lower stage 150. The first and second directions D1′ and D2′ may be parallel to the first surface 131 of the lower plate 130 and may intersect (e.g., be perpendicular to) each other. In an example embodiment, as illustrated in FIGS. 13 and 16, when the first magnets 134 are arranged in a matrix in directions inclined by approximately 45° from the first and second reference directions RD1 and RD2, the first and second directions D1′ and D2′ may be parallel to the directions inclined by approximately 45° from the first and second reference directions RD1 and RD2, respectively. For example, angles between the first direction D1′ and the first reference direction RD1 and between the second direction D2′ and the second reverence direction RD2 may be 45°.

Referring to FIGS. 13 to 15, each of the pattern spaces formed by the lower plate case 133 may have a diamond/rhombus shape in a plan view. For example, each of the pattern spaces may have a square shape in a plan view having each side extending in a direction having 45 degree with respect to sides of the lower plate 130 in the plan view. In an example embodiment, each of the pattern spaces may have sides parallel to the first direction D1′ and sides parallel to the second direction D2′, as illustrated in FIG. 14. In an example embodiment, the first magnets 134 may be arranged in a matrix, e.g., in the first and second directions D1′ and D2′, as illustrated in FIG. 14. Accordingly, the lower stage 150 may be moved in at least one of the first direction D1′, the second direction D2′, and the third direction D3, as illustrated in FIG. 13. In an example embodiment, the lower stage 150 may have sides parallel to the first direction D1′ and sides parallel to the second direction D2′ along the shape/arrangement of the pattern spaces formed by the lower plate case 133, as illustrated in FIG. 16. For example, the lower stage 150 may have a diamond/rhombus (e.g., a square) shape in a plan view. For example, each side of the lower stage 150 in a plan view may extend in a direction having an angle of 45 degree with respect to sides of the lower plate 130 in the plan view.

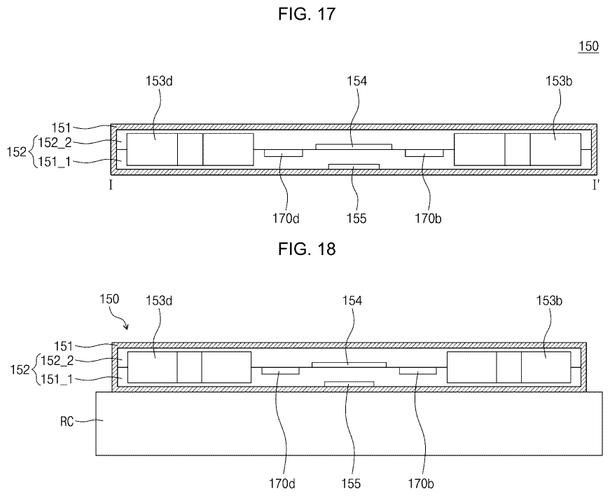

FIG. 17 is a cross-sectional view corresponding to line I-I′ of FIG. 5 and illustrating a semiconductor manufacturing apparatus according to an example embodiment. FIG. 18 is a cross-sectional view illustrating a charging method of a lower stage of a semiconductor manufacturing apparatus according to an example embodiment.

Referring to FIG. 17, the lower stage 150 may further include a power portion (e.g., a power supply) 154 and a charging induction portion (e.g., an inductor) 155. The power portion 154 may be configured to supply power to the current control portion 170 within the lower stage 150. The charging induction portion 155 may be configured to wirelessly charge the power portion 154. In addition, the charging induction portion 155 may be of an inductive type (e.g., an inductor) or a resonant type (e.g., a resonator). Accordingly, the lower stage 150 may supply power to the current control portion 170 without complex wirings for supplying power. The lower portion 152_1 of the insulating layer may cover the second magnets 153b and 153d, the charging induction portion 155, and the current control portions 170b and 170d. For example, the lower portion 152_1 of the insulating layer may cover/contact surfaces of the second magnets 153b and 153d, the charging induction portion 155, and the current control portions 170b and 170d. The upper portion 152_2 of the insulating layer may cover the second magnets 153a, 153b, 153c, and 153d and the power portion 154. For example, the upper portion 152_2 of the insulating layer may cover/contact surfaces of the second magnets 153a, 153b, 153c, and 153d and the power portion 154. For example, the lower portion 152_1 and the upper portion 152_2 of the insulating layer 152 may be formed by different/separate processes from each other. For example, the power portion 154 and the charging induction portion 155 may be provided within the insulating layer 152. In an example embodiment, the charging induction portion 155 may be provided on the bottom portion of the lower stage 150.

Referring to FIG. 18, the power portion 154 within the lower stage 150 may be charged on a wireless charger RC. To this end, the lower stage 150 may be provided at a location adjacent to the wireless charger RC and may be placed on the wireless charger RC. In an example embodiment, a process of charging the power portion 154 may be performed outside the bonding chamber 100, and thus, may be performed either before the lower stage 150 enters the bonding chamber 100 or after the lower stage 150 exits the bonding chamber 100.

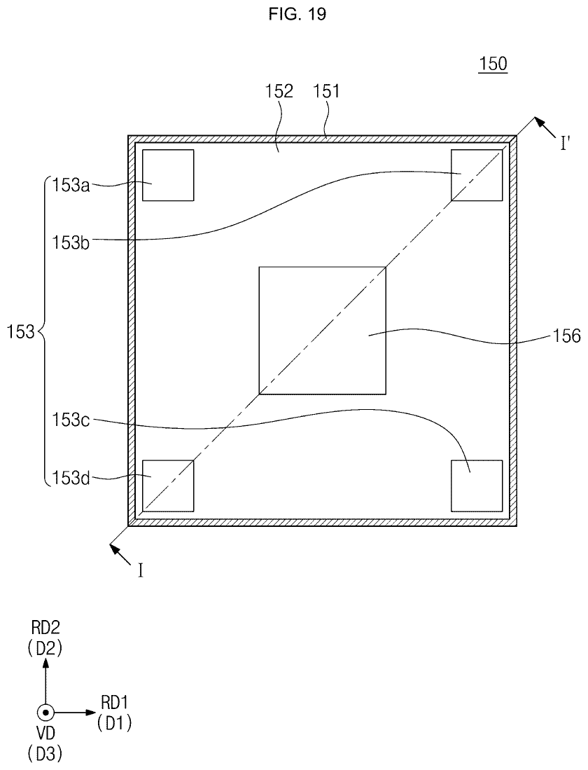

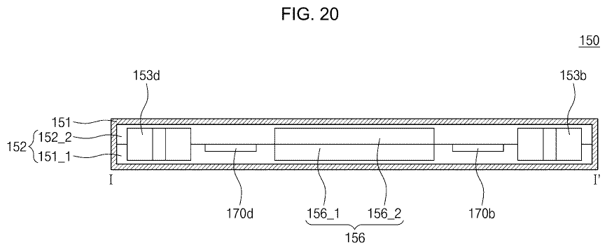

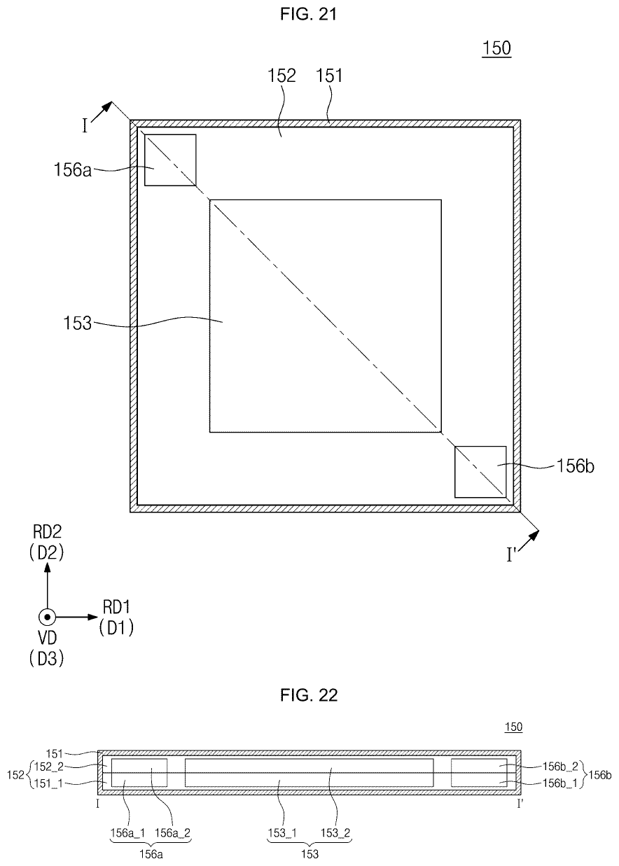

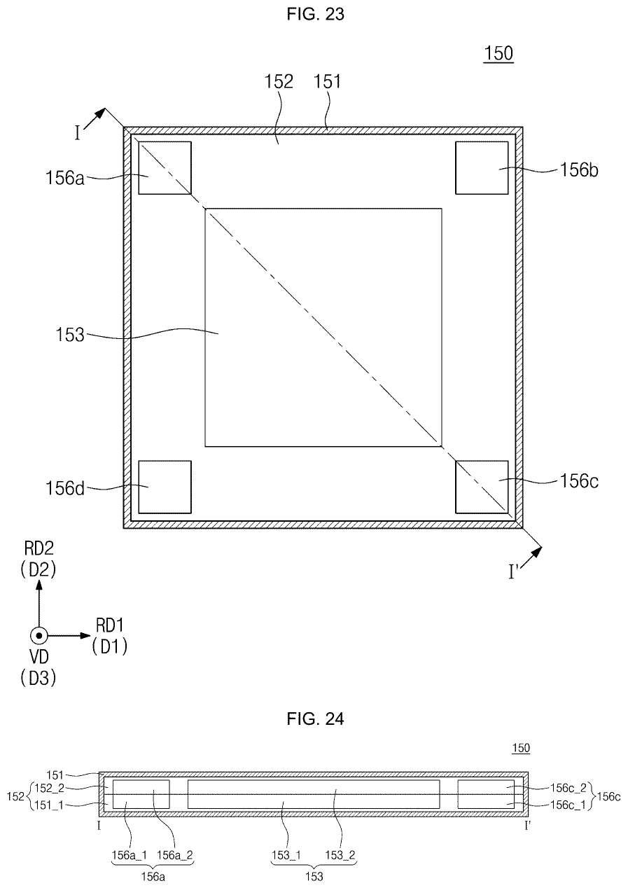

FIG. 19 is a plan view of a lower stage of a semiconductor manufacturing apparatus according to an example embodiment, and FIG. 20 is a cross-sectional view taken along line I-I′ of FIG. 19. FIG. 21 is a plan view of a lower stage of a semiconductor manufacturing apparatus according to an example embodiment, and FIG. 22 is a cross-sectional view taken along line I-I′ of FIG. 21. FIG. 23 is a plan view of a lower stage of a semiconductor manufacturing apparatus according to an example embodiment, and FIG. 24 is a cross-sectional view taken along line I-I′ of FIG. 23.

Referring to FIGS. 19 to 24, the lower stage 150 may further include a third magnet 156. The third magnet 156 may perform a portion of functions of the second magnet 153 and may be referred to by various names, including as an additional magnet, an auxiliary magnet, a levitation magnet, a floating magnet, or a rotation magnet, depending on the role that the third magnet 156 performs.

Referring to FIGS. 5, 6, 19, and 20, the third magnet 156 may be provided within a central region of the lower stage 150, and the four second magnets 153a, 153b, 153c, and 153d may be arranged to surround the central region of the lower stage 150 in a plan view. The third magnet 156 provided within the central region may include a lower portion 156_1 that is an N-pole magnet (or an N-pole of the third magnet 156) and an upper portion 156_2 that is an S-pole magnet (or S-pole of the third magnet 156). However, the inventive concept is not limited thereto, so that the lower portion 156_1 of the third magnet may be an S pole and the upper portion 156_2 of the third magnet may be an N pole in certain embodiments. In addition, the third magnet 156 may be covered with at least one of the lower portion 152_1 and the upper portion 152_2 of the insulating layer, and may be provided within the insulating layer 152. For example, at least one of the lower portion 152_1 and the upper portion 152_2 of the insulating layer may cover/contact a top surface, a bottom surface, and/or side surfaces of the third magnet 156. In an example embodiment, the third magnet 156 may be a single permanent magnet formed by coupling a permanent magnet corresponding to the lower portion 156_1 of the third magnet and a permanent magnet corresponding to the upper portion 156_2 of the third magnet. For example, the third magnet 156 may be a single permanent magnet having opposite polities at opposite ends, or the third magnet 156 may be a magnet formed by combining two permanent magnets. In an example embodiment, a bottom end (or a lower end) of the third magnet 156 may have the same polarity as top ends (or upper ends) of the first magnets 134, so that the lower stage 150 may levitate using magnetic force.

Referring to FIGS. 11, 12, 21, and 24, at least two third magnets 156 may be provided, and may be arranged to surround a second magnet 153 provided in the central region of the lower stage 150, e.g., in a plan view. For example, the at least two third magnets 156 may be disposed at edge portions of the lower stage 150, e.g., in the plan view.

For example, two third magnets 156a and 156b arranged to surround the second magnet 153 illustrated in FIGS. 21 and 22 may be provided to form a point symmetry, e.g., in a plan view, and each of the two third magnets 156a and 156b may include a lower portion that is an N pole and an upper portion that is an S pole. Accordingly, one third magnet 156a may include a lower portion 156a_1 of the third magnet, which is an N pole, and an upper portion 156a_2 of the third magnet, which is an S pole, and the other third magnet 156b may include a lower portion 156b_1 of the third magnet, which is an N pole, and an upper portion 156b_2 of the third magnet, which is an S pole. However, the polarities of the upper and lower portions are not limited to the above description, and the lower portions 156a_1 and 156b_1 of the third magnets may each be an S pole and the upper portions 156a_2 and 156b_2 of the third magnets may each be an N pole in certain embodiments.

For example, the four third magnets 156a, 156b, 156c, 156d arranged to surround the second magnet 153 illustrated in FIGS. 23 and 24 may be spaced apart from each other at equal distances (equidistantly) from the center of the lower stage 150 and may be arranged at equal angles (equiangularly) in a clockwise direction, in a plan view. Each of the four third magnets 156a, 156b, 156c, and 156d may include a lower portion, which is an N pole, and an upper portion, which is an S pole. Accordingly, the lower portions 156a_1, 156b_1, 156c_1, and 156d_1 of the third magnets may each be an N pole, and the upper portions 156a_2, 156b_2, 156c_2, and 156d_2 of the third magnets may each be an S pole. However, the polarities of the upper and lower portions are not limited to the above description, and the lower portions 156a_1, 156b_1, 156c_1, and 156d_1 of the third magnets may each be an S pole and the upper portions 156a_2, 156b_2, 156c_2, and 156d_2 of the third magnets may each be an N pole in certain embodiments.

The third magnets 156a, 156b, 156c, and 156d according to an example embodiment may have a weaker magnetism than the second magnet 153. The current control portion 170 according to an example embodiment may control directions of currents, respectively applied to the first magnets 134 that vertically overlap the third magnets 156a, 156b, 156c, and 156d, such that top ends of the first magnets 134 have a polarity different from that of the lower portions 156a_1, 156b_1, 156c_1, and 156d_1 of the third magnets, thereby fixing the lower stage 150 at a designated position. In addition, the current control portion 170 according to an example embodiment may control the directions of the currents, respectively applied to the first magnets 134 that vertically overlap the third magnets 156a, 156b, 156c, and 156d, such that top ends of the first magnets 134 have the same polarity as or different polarity from the lower portions 156a_1, 156b_1, 156c_1, and 156d_1 of the third magnets, thereby rotating the lower stage 150.

As described above, according to an example embodiment, the semiconductor manufacturing apparatus may reduce misalignment caused by an alignment process and a bonding process by levitating or floating the lower stage 150 on the lower plate 130. When the alignment process and the bonding process are performed without separating the lower stage 150 from the lower plate 130, the likelihood of misalignment arising from vibration and friction of the device may increase. For example, the semiconductor manufacturing apparatus according to an example embodiment may significantly reduce misalignments to improve reliability of the bonded substrates S1 and S2.

In addition, according to some embodiments, the third magnet 156 may be provided in the lower stage 150, and thus the third magnet 156 may play either a role of levitating the lower stage 150 or a role of rotating the lower stage 150. As a result, the movement of the lower stage 150 may be controlled more easily and more precisely.

As set forth above, according to example embodiments, a lower stage may levitate from the upper surface of the lower plate during a bonding process. Accordingly, vibration and/or air friction, which may be applied to a substrate, may be significantly reduced. As a result, the reliability of the bonding process may be improved.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments have been shown and described above, it will be apparent to those skilled in the art that modifications and variations could be made without departing from the scope of the invention as defined by the appended claims.

What is claimed is:

1. A semiconductor manufacturing apparatus comprising:
a bonding chamber comprising a lower frame and an upper frame provided on the lower frame and having an internal space;
a lower plate provided on the lower frame within the internal space, comprising first magnets arranged in a matrix, and having a first surface and a second surface opposing the first surface;
a lower stage comprising at least one second magnet and configured to levitate above the first magnets using magnetic force;
a current controller configured to apply current to the first magnets or the at least one second magnet and control at least one of a direction and an intensity of the current;
an upper plate having a third surface facing the first surface, the upper plate connected to a lower surface of the upper frame; and
an upper stage provided on the third surface of the upper plate.

2. The semiconductor manufacturing apparatus of claim 1, wherein
the first magnets are permanent magnets,
the at least one second magnet is at least one an electromagnet, and
the current controller is provided in the lower stage to be electrically connected to the at least one second magnet.

3. The semiconductor manufacturing apparatus of claim 1, wherein
the first magnets are electromagnets,
the at least one second magnet is at least one permanent magnet, and
the current controller is electrically connected to the first magnets and is configured to independently control each of the first magnets.

4. A semiconductor manufacturing apparatus comprising:
a bonding chamber comprising a lower frame and an upper frame provided on the lower frame and having an internal space;
a lower plate provided on the lower frame, comprising permanent magnets arranged in a matrix, and having a first surface and a second surface opposing the first surface;
a lower stage configured to levitate above first magnets using magnetic force and comprising at least one electromagnet and a current controller configured to apply current to the at least one electromagnet and control at least one of a direction and an intensity of the current;
an upper plate having a third surface facing the first surface, the upper plate connected to a lower surface of the upper frame; and
an upper stage provided on the third surface of the upper plate.

5. The semiconductor manufacturing apparatus of claim 4, wherein
the at least one electromagnet comprises four electromagnets spaced apart from each other.

6. The semiconductor manufacturing apparatus of claim 5, wherein
the current controller is configured to control directions of currents, respectively applied to the four electromagnets, to move the lower stage in at least one of a first direction and a second direction, and
the first and second directions are parallel to the first surface of the lower plate and intersect each other.

7. The semiconductor manufacturing apparatus of claim 5, wherein
the current controller is configured to control directions of currents, respectively applied to at least two of the four electromagnets, to rotate the lower stage.

8. The semiconductor manufacturing apparatus of claim 5, wherein
the current controller is configured to control an intensity of currents, respectively applied to the four electromagnets, to move the lower stage in a third direction, and
the third direction is perpendicular to the first surface of the lower plate.

9. The semiconductor manufacturing apparatus of claim 5, wherein
the four electromagnets are arranged to surround a central region of the lower stage in a plan view, and
the lower stage further comprises an additional magnet disposed in the central region of the lower stage.

10. The semiconductor manufacturing apparatus of claim 5, wherein
the four electromagnets are spaced apart from each other at equal distances from a center of the lower stage and arranged at equal angles in a clockwise direction.

11. The semiconductor manufacturing apparatus of claim 4, wherein the lower plate further comprises an insulating plate covering the first magnets.

12. The semiconductor manufacturing apparatus of claim 4, wherein
the lower frame comprises a bottom portion and a wall portion connected to an edge of the bottom portion,
the internal space of the bonding chamber is defined as a space surrounded by the bottom portion and the wall portion of the lower frame, and
the upper frame is removable from an upper end of the wall portion of the lower frame.

13. The semiconductor manufacturing apparatus of claim 4, wherein
the lower stage further comprises a power supply configured to supply power to the current controller and a charging induction portion configured to wirelessly charge the power supply.

14. A semiconductor manufacturing apparatus comprising:
a bonding chamber comprising a lower frame and an upper frame provided on the lower frame and having an internal space;
a lower plate provided on the lower frame, the lower plate comprising electromagnets arranged in a matrix, the lower plate having a first surface and a second surface opposing the first surface;
a current controller configured to apply current to the electromagnets and to control at least one of a direction and an intensity of the current;
a lower stage configured to levitate above the electromagnets using magnetic force and comprising at least one permanent magnet;
an upper plate having a third surface facing the first surface, the upper plate connected to a lower surface of the upper frame; and
an upper stage provided on the third surface of the upper plate.

15. The semiconductor manufacturing apparatus of claim 14, wherein
the current controller is configured to control directions of currents, applied to the electromagnets vertically overlapping the at least one permanent magnet and electromagnets surrounding the vertically overlapping electromagnets, to move the lower stage in at least one of a first direction and a second direction, and
the first and second directions are parallel to the first surface of the lower plate and intersect each other.

16. The semiconductor manufacturing apparatus of claim 14, wherein
the current controller is configured to control directions of currents, applied to at least a portion of the electromagnets vertically overlapping the at least one permanent magnet, to rotate the lower stage.

17. The semiconductor manufacturing apparatus of claim 14, wherein
the current controller is configured to control intensities of currents, applied to the electromagnets vertically overlapping the at least one permanent magnet, to move the lower stage in a third direction.

18. The semiconductor manufacturing apparatus of claim 14, wherein
the lower stage further comprises additional magnets disposed on sides of the at least one permanent magnet, and
the additional magnets are permanent magnets.

19. The semiconductor manufacturing apparatus of claim 14, wherein the current controller is configured to independently control each of the electromagnets.

20. The semiconductor manufacturing apparatus of claim 14, wherein the lower plate further comprises an insulating plate covering the electromagnets.
